(19) United States
(12) Patent Application Publication
(10) Pub. No.: US 2006/0171001 A1
(43) Pub. Date: Aug. 3, 2006

(54) Image forming apparatus

(75) Inventors: Takashi Kitagawa, Yamatokoriyama-shi (JP); Shinji Imagawa, Ikoma-gun (JP); Tatsuya Tanaka, Yamatokoriyama-shi (JP); Hiroshi Kawano, Yamatokoriyama-shi (JP); Kyosuke Taka, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/344,479

(22) Filed: Feb. 1, 2006

(30) Foreign Application Priority Data
Feb. 2, 2005 (JP) 2005-027049
Feb. 2, 2005 (JP) 2005-027051
Feb. 9, 2005 (JP) 2005-033654

(51) Int. Cl. G03F 3/08

(52) U.S. Cl. 358/521

(57) ABSTRACT

In a case where the density correction condition of an image output section is satisfied while a job is being executed, density correction means performs density correction while the job is being executed or after the execution of the job. On this occasion, if there is a job on standby for printing in an image memory, this job is executed in the image formation condition (i.e. a correction amount stored in a current correction amount storing section) determined before the density correction. In the meanwhile, a job which is stored after the density correction is executed in a latest image formation condition (i.e. a correction amount stored in a latest correction amount storing section) which is figured out by the aforesaid density correction.

This Nonprovisional application claims priority under 35 U.S.C. § 119(a) on Patent Application No. 033654/2005 filed in Japan on Feb. 9, 2005, Patent Application No. 027051/2005 filed in Japan on Feb. 2, 2005, and Patent Application No. 027049/2005 filed in Japan on Feb. 2, 2005, the entire contents of which are hereby incorporated by reference.

### FIELD OF THE INVENTION

The present invention relates to an electrophotographic image forming apparatus such as photocopiers and printers, and particularly relates to an image forming apparatus that detects conditions for density correction while image formation (printing) is carried out, and performs the density correction when the density correction condition is satisfied.

### BACKGROUND OF THE INVENTION

In electrophotographic image forming apparatuses, the image quality (density) of a printed matter changes because the apparatus changes over time, e.g. the deterioration of a photoconductor. Therefore, to stably perform the printing with a constant image quality, the image forming apparatuses are required to appropriately perform density correction. The density correction is typically performed by changing an image formation condition such as a developing bias voltage and a charging bias voltage.

To perform such density correction, the image forming apparatus monitors whether or not predetermined density correction condition is satisfied. Once it is determined that the density correction condition is satisfied, the density correction is carried out. Example of cases where the density correction condition is satisfied are, for example, a case where the image forming apparatus is turned on power, a case where a toner cartridge is replaced with a new one, and a case where the number of output sheets reaches a predetermined number.

Recently, image forming apparatuses are provided with an image memory capable of storing a plurality of jobs. When the image forming apparatus is required to execute a print job while another print job is being executed, the newly-required print job is stored in the image memory. The print jobs stored in the image memory are executed in the order in which the jobs are stored in the image memory.

Examples of the print jobs performed by the image forming apparatus are: data which is read out by an image reading apparatus; and data supplied from a computer which is connected to the image forming apparatus via a network. The print job is performed after the supplied data is subjected to image processing such as a gamma process and screen process.

In the image forming apparatus, the print job on standby in the image memory has been subjected to the image processing (gamma process and screen process) for the purpose of allowing the print job to be promptly performed when its turn comes. This arrangement is disclosed in Japanese Laid-Open Patent Application No. 11-289436/1999 (published on Oct. 19, 1999; hereinafter, Patent Document 1).

The above-described conventional arrangement causes the following problem, in a case where the density correction condition is satisfied while the printing is carried out.

That is, there is a case where the density correction condition is satisfied because the number of printing since the previous density correction was performed reaches a predetermined number, while a print job is being executed. In such a case, if the active job is interrupted and the density correction is carried out, the image formation condition is changed while the active job is being executed. For this reason, the image quality of the printed matter changes in the middle of the prosecution of the job.

In the meanwhile, in a case where an active job exists when the density correction condition is satisfied, the density correction may be performed after the job is executed. However, in this case, if the image memory stores another job when the density correction condition is satisfied, said another job stored in the image memory is not executed in a suitable image formation condition.

This problem occurs on account of disagreement between (i) the image processing (gamma process and screen process) to which the job is subjected and (ii) the image formation condition at the time of executing the print job. That is, before being executed, the job is stored in the image memory, in a state of having been subjected to the image processing such as the gamma process and screen process. Since the image processing correlates with the image formation condition at the time of performing the printing, it is necessary to cause the image processing to which the job is subjected to agree with the image formation condition at the time of the printing.

For this reason, in a case where the density correction is performed so that the image formation condition is changed while the image memory stores the job having been subjected to the image processing, the image processing to which the job has been subjected disagrees with the image formation condition at the time of the printing. The printing is therefore not carried out in suitable image formation condition. This problem is conspicuous in a case of printing a color image.

The above-described problem can be avoided by performing the density correction after all print jobs stored in the image memory are executed. However, in this case, the density correction is retarded even if the density correction condition is satisfied. There is hence a possibility that many print jobs are executed without the density correction. In particular, in a case where the image forming apparatus is required to perform many print jobs and hence the image memory stores the jobs for a long period of time, inappropriate printing may be performed many times because many jobs are not subjected to the density correction.

Meanwhile, in a case where the image memory stores a job when the density correction condition is satisfied, the following may be carried out: the density correction is performed before the execution of the stored job, and then the job is subjected again to the image processing (gamma process and screen process) corresponding to the image formation condition after the density correction. However, in this case, since the job stored in the image memory is subjected to the image processing again, the image processing section of the image forming apparatus has to bear a heavy burden. In the case above, furthermore, since the execution of the print jobs on standby is retarded, the printing performance of the image forming apparatus decreases.

### SUMMARY OF THE INVENTION

The objective of the present invention is to provide an image forming apparatus that can speedily perform density correction and suitably execute all print jobs stored in an image memory.

To achieve the objective above, a first image forming apparatus of the present invention, which includes an electrophotographic image forming section, is provided with: an image memory capable of storing sets of image data corresponding to a plurality of jobs: an image processing section that performs image processing with respect to a set of image data to be outputted: and a density correction section that changes an image formation condition of the image forming section, for causing the image forming section to perform the density correction in a case where the image forming section satisfies a density correction condition, a set of image data which is on standby for printing being stored in the image memory, in a state of having been subjected to at least a part of the image processing performed by the image processing section, in a case where the density correction condition of the image forming section is satisfied while a job is being executed, the density correction being performed either while the job is being executed or after the job is executed, and a job, which has been stored in the image memory when the image forming section satisfies the density correction condition, being executed in an image formation condition determined before the density correction is performed.

According to the arrangement above, in a case where the density correction condition of the image forming section is satisfied while a job is being executed, the density correction is performed while the job is being executed or after the execution of the job. On this account, after the timing to perform the density correction comes, the substantial retardation of the density correction is prevented, and hence the density correction is promptly carried out.

If a job on standby for printing exists in the image memory when the density correction condition of the image forming section is satisfied, this job is executed after the density correction. Meanwhile, such a job on standby is executed in the image formation condition determined before the density correction. With this, the image processing (gamma process and screen process) to which the job has been subjected in advance agrees with the image formation condition at the time of executing the job, and hence the printing is suitably carried out.

To achieve the objective above, a second image forming apparatus of the present invention, which includes an electrophotographic image forming section, is provided with: an image memory capable of storing sets of image data corresponding to a plurality of jobs: an image processing section that performs image processing with respect to a set of image data to be outputted: and a density correction section that changes an image formation condition of the image forming section, for causing the image forming section to perform the density correction in a case where the image forming section satisfies a density correction condition, a set of image data which is on standby for printing being stored in the image memory, in a state of having been subjected to at least a part of the image processing performed by the image processing section, and when the density correction condition of the image forming section is satisfied while a job is being executed, jobs stored in the image memory being classified into color jobs and monochrome jobs, the density correction being performed after the color jobs are preferentially executed, and the monochrome jobs being executed after the density correction is performed.

According to the arrangement above, after the color jobs are executed, the density correction is carried out. On this account, as to the color jobs, the image processing to which the jobs are subjected agrees with the image formation condition at the time of executing the job. Therefore, it is possible to surely prevent the significant deterioration of image quality, which occurs when the image processing to which the job is subjected disagrees with the image formation condition at the time of executing the job.

As to the monochrome jobs, significant deterioration of image quality does not occur even if the image quality to which the jobs are subjected disagrees with the image formation condition at the time of executing the job. For this reason, the monochrome jobs are executed after the density correction. With this, it is possible to prevent the implementation of the density correction from being unnecessarily retarded, and hence long-term stability of the image quality is assured.

To achieve the objective above, a third image forming apparatus of the present invention, which includes an electrophotographic image forming section, is provided with: an image memory capable of storing sets of image data corresponding to a plurality of jobs: an image processing section that performs image processing with respect to a set of image data to be outputted: and a density correction section that changes an image formation condition of the image forming section, for causing the image forming section to perform the density correction in a case where the image forming section satisfies a density correction condition, a set of image data which is on standby for printing being stored in the image memory, in a state of having been subjected to at least a part of the image processing performed by the image processing section, and when the density correction condition of the image forming section is satisfied while a job is being executed, the density correction being performed in a normal mode if there is no job in the image memory, meanwhile, when the density correction condition of the image forming section is satisfied while a job is being executed, the density correction being performed in a simple mode in which a time required for the density correction is short as compared to the normal mode, if there is a job in the image memory.

According to the arrangement above, in a case where the density correction condition is satisfied while a job is being executed, the density correction is carried out after the execution of the job. On this account, after the timing to carry out the density correction comes, the substantial retardation of the density correction of prevented, and the density correction is promptly carried out.

In a case where a job on standby for printing is stored in the image memory when the density correction condition of the image forming section is satisfied, the density correction is performed in the simple mode with which a time required for the density correction is short as compared to the normal mode. The job on standby is therefore executed after the density correction. A time required for this density correction is shorter than that for the normal density correction. On this account, a time for standby is minimized and the deterioration of the printing performance is restrained.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a block diagram showing a substantial part of an image forming apparatus of Embodiment 1 of the present invention.

FIG. 2 is a cross section that outlines the image forming apparatus of the present invention.

FIG. 3 is a block diagram that outlines an image processing section of the image forming apparatus.

FIG. 4 shows the relationship between the density correction and the execution of a print job, in the image forming apparatus.

FIG. 5 is a block diagram showing a substantial part of an image forming apparatus of Embodiment 2.

FIG. 6 shows the relationship between the density correction and the execution of a print job, in the image forming apparatus.

FIG. 7 is a block diagram showing a substantial part of an image forming apparatus of Embodiment 3.

FIG. 8(a) shows the relationship between the density correction and the execution of a print job, in a case where an image memory of the image forming apparatus stores another job.

FIG. 8(b) shows the relationship between the density correction and the execution of a print job, in a case where the image memory of the image forming apparatus does not store a job.

### DESCRIPTION OF THE EMBODIMENTS

### Embodiment 1

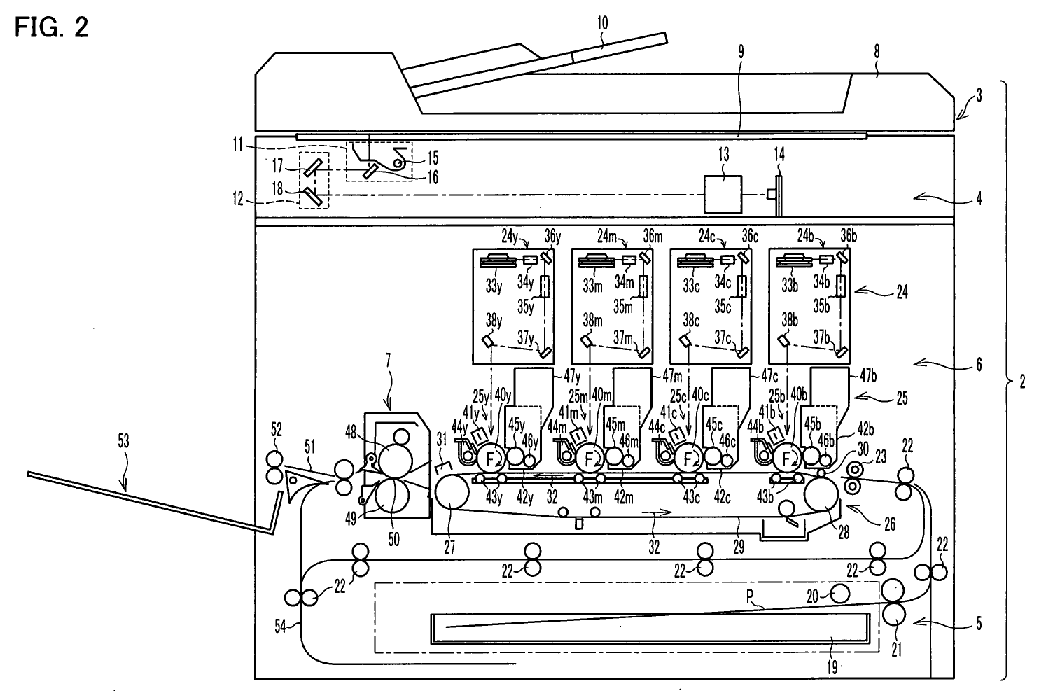

The following will describe an embodiment of the present invention in reference to figures. First, the outline of an image forming apparatus of the present embodiment is described in reference to FIG. 2.

FIG. 2 shows a photocopier 2 which is a type of the image forming apparatus. The photocopier 2 includes a document supply section 3, an image reading section 4, a paper feeding section 5, an image forming section 6, and a fixing section 7.

The document supply section 3 includes a reversing automatic document feeder (abbreviated as RADF) 8, a document supporter 9 on which a document supplied from the RADF 8 is provided in a predetermined position, and a document receiving tray 10. There is a certain positional relationship between the RADF 8 and the document supporter 9, and the RADF 8 is supported in such a manner as to be openable and closable. The RADF 8 supplies a document in such a manner that one surface of the document is placed at a predetermined position on the document supporter 9, at which position the surface facing the image reading section 4. After the reading of an image from said one surface finishes, the RADF 8 reverses and supplies the document in such a manner that the other surface of the document is placed at a predetermined position on the document supporter 9, at which position the other surface facing the image reading section 4. After the reading of an image from the other surface of the document, the RADF 8 discharges the document to the document receiving tray 10. The supply and reverse of the document are controlled in association with the overall operation of the photocopier 2. In a case where only one surface of a document is photocopied, the reverse-supply of the document is not carried out.

The image reading section 4 is provided below the document supporter 9, and reads an image from a document supplied to the document supporter 9 by the RADF 8. The image reading section 4 includes: first and second scanning units 11 and 12 that horizontally reciprocate along the bottom surface of the document supporter 9; an optical lens 13; and a CCD (Charge Coupled Device) line sensor 14 which is a photoelectric conversion element.

The first scanning unit 11 includes: an exposure lamp 15 that exposes, to light, the surface of a document to be read; and a first mirror 16 that deflects, in a predetermined direction, the reflected optical image from the document. The first scanning unit 11 reciprocates at a predetermined scanning speed, while the distance between the first scanning unit 11 and the bottom surface of the document supporter 9 is kept constant. The second scanning unit 12 includes second and third mirrors 17 and 18 that further deflect, in a predetermined direction, the reflected optical image having been deflected by the first mirror 16 of the first scanning unit 11. The second scanning unit 12 horizontally reciprocates along the bottom surface of the document supporter 9, while the relative speed between the first and second scanning units 11 and 12 is kept constant.

The optical lens 13 reduces the size of the reflected optical image deflected by the third mirror 18 of the second scanning unit 12, and causes the image to focus at a predetermined position on the CCD line sensor 14. The CCD line sensor 14 reads a monochrome image or a color image, and, as a 3-line color CCD, the CCD line sensor 14 outputs line data in which the image is separated into red (R), green (G), and blue (B) color components. The CCD line sensor 14 serially subjects each reflected optical image, which is focused on account of the optical lens 13, to the photoelectric conversion, so as to output an electric signal. The document image information as an electric signal is supplied from the CCD line sensor 14 to the image forming section 6.

The paper feeding section 5 is provided in the lowest part of the photocopier 2. The paper feeding section 5 includes: a paper tray 19 that stores stacked recording sheets P each of which is a recording medium; and a separation roller 20 and a paper feeding roller 21, which separate the recording sheets P in the paper tray 19 and transport the sheets, in one-by-one manner. Each of the recording sheets P, which are separated and taken out from the paper feeding section 5 in one-by-one manner, is transported to the point immediately before the image forming section 6, by transport rollers 22 provided along the transport path of the recording sheets P. Then each of the transport sheets P is supplied to the image forming section 6. The timing to supply the transport sheet P to the image forming section 6 is controlled by a pair of resist rollers 23 provided at a point immediately before the image forming section 6.

The image forming section 6 is provided between the image reading section 4 and the paper feeding section 5, and includes laser beam scanner units 24, image forming stations 25, and a transfer/transport belt mechanism 26. The transfer/transport belt mechanism 26 is provided below the image forming section 6, and includes: a driving roller 27; a driven roller 28; a belt 29 supported by the driving roller 27 and the driven roller 28; an attaching charger 30 that electrically charges the surface of the belt 29 so as to cause the recording sheet P to be attached onto the surface; and a discharger 31 that peels off the recording sheet P which has been attached onto the belt 29.

The belt 29 rotates in the direction indicated by an arrow 32, in response to the rotation of the drive roller 27 around the axis. The recording sheet P, which is supplied at a timing controlled by the resist rollers 23, is electrostatically attached onto the belt 29 whose surface is electrically charged by the attaching charger 30, and the recording sheet P is transported in the direction of the arrow 32. While the recording sheet P is transported in the direction of the arrow 32 by the belt 29, an image is transferred onto the recording sheet P. The recording sheet P on which the image has been transferred is peeled off from the belt 29 by the discharger 31, and then transported to the fixing section 7. The control of the supply of the sheet by the resist rollers 23 is carried out in such a manner that, the front edge of the recording sheet P is detected by a sensor (not illustrated), and the control is carried out in line with the result of the detection outputted from the sensor.

Since the photocopier 2 supports color printing, four pairs of laser beam scanner units 24 and image forming stations 25 are provided for the respective colors of black, cyan, magenta, and yellow. The pairs of the laser beam scanner units 24 and the image forming stations 25 are identical with each other except that, in each of the pairs, the color of the toner for development is black, cyan, magenta, or yellow, and a supplied pixel signal corresponds to a black color component image, cyan color component image, magenta color component image, or yellow color component image. The description below relates only to the laser beam scanner unit 24 and image forming station 25 for the black color, and the descriptions in regard of the remaining ones are omitted. In a case where the laser beam scanner units 24 and the image forming stations 25 are distinguished from one another, alphabets b (black), c (cyan), m (magenta), and y (yellow) is suffixed.

The laser beam scanner unit 24b includes: a semiconductor laser element (not illustrated) that emits dot light which is modulated in accordance with the image document information supplied from the image reading section 4; a polygon mirror 33b that deflects, in the main scanning direction, a laser beam emitted from the semiconductor laser element; fθ lenses 34b and 35b that focus the laser beam, which has been deflected by the polygon mirror 33b, on the surface of an electrophotographic photoconductor 40b (hereinafter, photoconductor); and reflecting mirrors 36b, 37b, and 38b. The surface of the photoconductor 40b of the image forming station 25b is exposed to the laser beam reflected on the reflecting mirror 38b, so that an electrostatic latent image is formed.

The image forming station 25b includes the photoconductor 40b which is supported so as to be freely rotatable around an axis 39b, in the direction of an arrow F. The image forming station 25b further includes the following members provided along the circumference of the photoconductor 40b: a charger 41b that uniformly charges the surface of the photoconductor 40b, before the surface is exposed to the laser beam; a developer 42b that develops and visualizes the electrostatic latent image formed on the surface of the photoconductor 40b, thanks to the exposure to the laser beam emitted from the laser beam scanner unit 24b; a transfer discharger 43b that transfers, onto the recording sheet P on the belt 29, the developed image that faces the photoconductor 40b with the belt 29 interposed therebetween; and a cleaning unit 44b that removes and collects the toner remaining on the surface of the photoconductor 40b, after the development of the electrostatic latent image. The charger 41b, the developer 42b, the transfer discharger 43b, and the cleaning unit 44b are provided in this order, along the rotational direction indicated by the arrow F.

The charger 41b uniformly charges the surface of the photoconductor 40b, by means of electric discharge. The uniformly-charged surface of the photoconductor 40b is exposed to the laser beam which is supplied from the laser beam scanner unit 24b and corresponds to the image document information. As a result of the exposure, the electric charge quantity in an exposed part becomes different from the electric charge quantity in an non-exposed part, so that the electrostatic latent image is formed.

The developer 42b includes: a developing roller 45b that faces the photoconductor 40b; a developing agent transport roller 46b that supplies, to the developing roller 45b, a developing agent including toner; and a casing 47b that supports, in a rotatable manner, the developing roller 45b and the developing agent transport roller 46b, and that stores the developing agent therein. The developing agent is supplied from the developing roller 45b of the developer 42b to the surface of the photoconductor 40b on which the electrostatic latent image has been formed, so that the electrostatic latent image is developed and visualized. As described above, the visualized image is transferred onto the recording sheet P on the belt 29.

While being attached to the belt 29, the recording sheet P on which the black image has been transferred is transported in the direction of the arrow 32. As the recording sheet P passes through the cyan, magenta, and yellow image forming stations 25c, 25m, and 25y that are provided in this order from the upstream to the downstream of the transport path, cyan, magenta, and yellow images are serially transferred onto the recording sheet P, as in the case of the black image. In this manner, a full-color image is formed on the recording sheet P. The recording sheet P on which the full-color image has been formed is peeled off from the belt 29 by the discharger 31, and then sent to the fixing section 7.

The fixing section 7 includes: a heating roller 48 including heating means (not illustrated); and a pressure roller 49 which faces the heating roller 48. The pressure roller 49 is pushed onto the heating roller 48 so as to form a contact site, i.e. form a nip site 50 with the heating roller 48. The recording sheet P supplied to the fixing section 7 is heated and pressurized while passing through the nip site 50. As a result, the developing agent on the recording sheet P is fixed so that the image is firmly fixed.

In a case where an image is formed only on one surface or where an image is formed on the other surface after the image formation on the one surface was finished, the recording sheet P on which the fixation has been performed by the fixing section 7 is transported upward by the operation of a switching gate 51, and then discharged to a paper discharge tray 53 by discharge rollers 52. In a case where, subsequent to the image formation on one surface of the recording sheet P, the image formation on the other surface is performed, the recording sheet P is transported downward by the operation of the switching gate 51. The recording sheet P is reversed by a switchback transport path 54, and then transported to the image forming section 6 again. After being transported to the image forming section 6, the image formation as in the case above is performed on the recording sheet P.

The image forming apparatus shown in FIG. 2 is a mere example, and the present invention is not limited thereto. The image forming apparatus of the present invention may be a photocopier, a printer, or a multifunction device capable of functioning as both of them. The image forming apparatus of the present invention may be capable of performing color printing, or may be capable of printing only black-and-white images.

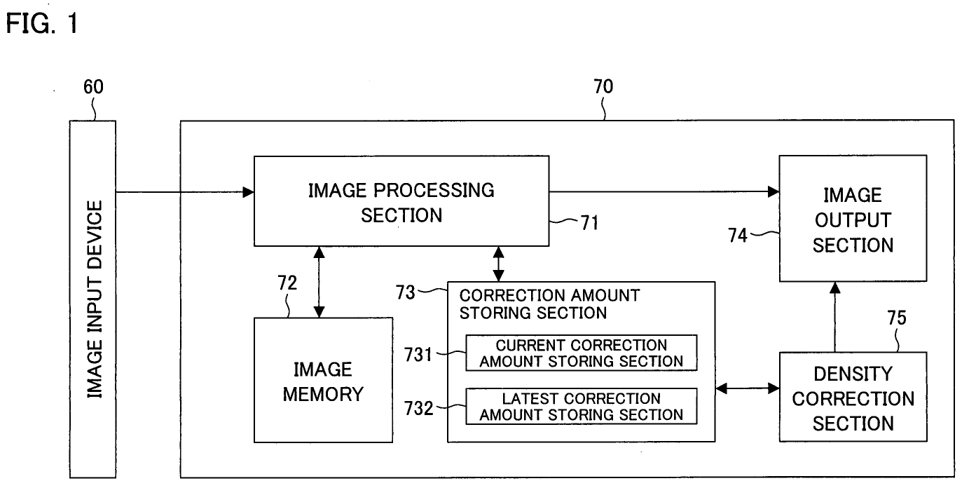

The image forming apparatus of the present invention forms images by electrophotography, and includes an image memory that can store a plurality of jobs. As an embodiment of the image forming apparatus of the present invention, FIG. 1 shows a digital color photocopier. As shown in the figure, the digital color photocopier includes an image input device 60 and an image output device 70.

The image input device 60 includes, for example, a scanner section provided with a CCD (Charge Coupled Device). Using the CCD, the image input device 60 reads out, as RGB (Red, Green, and Blue) analog signals, a reflected optical image from the document, and outputs the image thus read to the image output device 70. The image output device 70 subjects the image data, which is supplied from the image input device 60, to predetermined image processing, and outputs the image data, which has been subjected to the image processing, onto a recording medium (e.g. paper). The image formation is carried out by electrophotography. It is noted that the image input section 60 is not necessarily included in the image forming apparatus of the present invention. The image input section 60 may be externally connected to the image forming apparatus. Also, the image input section 60 is not necessarily a scanner. The image input section 60 may be an information processing device that supplies the image data to the image output device 70 via a network, e.g. a personal computer.

The image output device 70 includes an image processing section 71, an image memory 72, a correction amount storing section 73, an image output section 74, and a density correction section 75. These members of the image output device 70 are controlled by a control section (not illustrated).

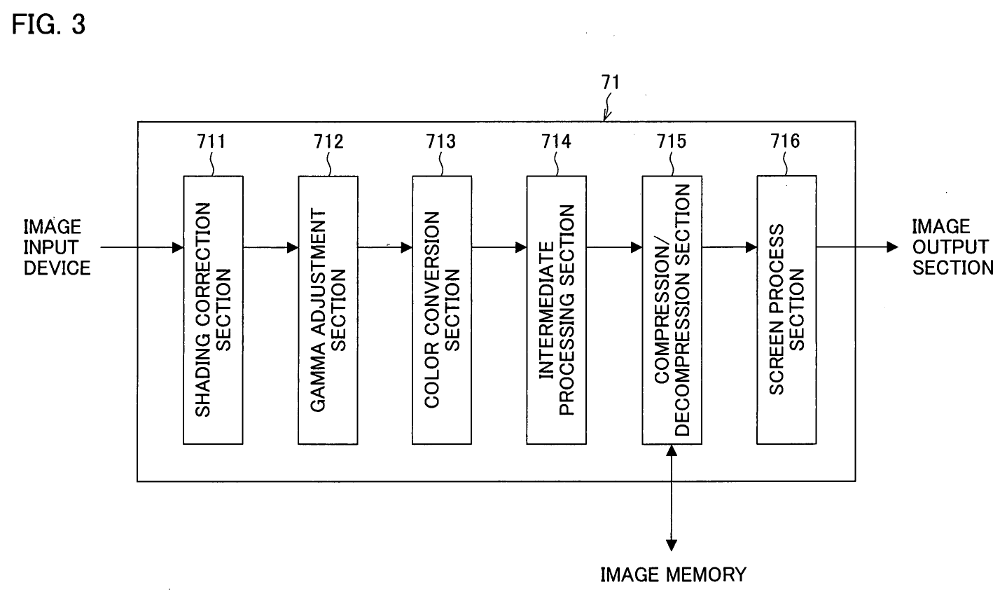

The image processing section 71 subjects the image data, which is supplied from the image input device 60, to the image processing including the gamma process and screen process, and outputs the image data to the image output section 74. FIG. 3 specifically shows the image processing section 71.

The image processing section 71 performs the following processes with respect to the image data supplied from the image input device: (i) using a shading correction section 711, smoothing, sharpness improvement, and zooming; (ii) using a gamma adjustment section 712, a gamma process such as brightness/density conversion in accordance with the tone characteristics of the image output section 74, copy density correction, or the like; (iii) using a color conversion section 713, color conversion from RGB to CMYK; and (iv) using an intermediate processing section 714, dithering and error diffusion. Then the image processing section 71 compresses the image data by a compression/decompression section 715, and stores the image data in the image memory 72 under the control of the control section.

Receiving the instruction from the control section to output the image data, the image processing section 71 reads out the image data from the image memory 72, and decompresses the image data by the compression/decompression section 715. Then the image processing section 71 subjects the image data thus read out to the screen process such as pulse width modulation for each of C, M, Y, and K of the image data, which process is performed using a screen process section 716, and the image processing section 71 outputs the image data to the image output section 74. As described above, the basic processes performed by the image processing section 71 are the color conversion, gamma process, and screen process. In the example shown in FIG. 3, the image data before being subjected to the screen process is stored in the image memory 72. Alternatively, the image data having been subjected to the screen process may be stored in the image memory 72.

The image memory 72 temporarily stores the image data supplied from the image input device 60, i.e. stores a print request job. The image forming apparatus includes the image memory 72. On this account, when the image forming apparatus is requested to perform a print job while another job is being executed, the job regarding the new printing request is stored in the image memory 72. In this manner more than one jobs are stored.

Subsequently, the density correction in the image output section 74 is discussed. In the image forming apparatus, the density correction is carried out in such a manner that the density correction section 75 changes the image formation condition of the image output section 74.

That is, the density correction is carried out as follows: prior to typical image formation, a toner image is actually formed on the photoconductor, transfer material transport belt, or the like, and the image formation condition with which a desired density is obtained is worked out by, for example, measuring the optical characteristics of the toner image, e.g. an amount of reflected light.

Such density correction is performed when power is supplied, when the toner cartridge is replaced, or when a certain number of sheets are outputted. For the density correction, a plurality of patch images corresponding to a predetermined density are formed on the photoconductor drum. Then the patch images are exposed to light, developed, and consequently transferred onto the transfer material transport belt. Then the density of the patch images transferred onto the transfer material transport belt is measured by the density detection sensor.

The density of the patch images, which has been measured by the density detection sensor, is notified of the density correction section 75, and the density correction section 75 compares the density with a density reference value. The density correction section 75 performs the density correction if the density of the patch images disagrees with the density reference value. In other words, the density correction section 75 changes the image formation condition of the image output section 74, in such a manner as to cause the density of the patch images to agree with the density reference value. There are several methods for carrying out the density correction, for example: (1) changing the developing bias voltage; (2) changing the charging potential at the maximum exposing light emission; and (3) changing the circumferential velocity ratio of the developing sleeve. That is, the image formation condition figured out by the density correction section 75 while the density correction is performed is stored in the correction amount storing section 73, as a correction amount indicating to what extent the developing bias voltage, the charging potential, and the like are corrected.

In a case where the image forming apparatus forms a color image, the density correction is performed for the image forming section of each color.

The density correction section 75 may perform, as the density correction, high-density correction and intermediate-density correction. That is to say, in the high-density correction, toner amount detection means detects the density of a high-density toner pattern, and the detected density is compared with a high-density reference value. If the detected density disagrees with the high-density reference value, the high-density correction is carried out. In the meanwhile, in the intermediate density correction, on condition that the image adjustment for high density is assured, the toner detection means detects the density of an intermediate-density toner pattern. If the detected intermediate density is disagree with an intermediate-density reference value as a result of the comparison, the intermediate density correction is carried out.

The objective of the image forming apparatus of the present embodiment is as follows: in a case where the density correction condition is satisfied while a print job is being executed, and at the same time the image memory stores image data on standby, the density correction is promptly carried out and also all print jobs stored in the image memory are suitably executed.

Assume that a print job being executed is interrupted and the density correction is carried out, while the density correction condition is satisfied. In such a case, the job on standby, which has been subjected to the gamma process and screen process and is stored in the image memory 72, is executed using the density correction amount (current correction amount) before the implementation of the density correction. In the meanwhile, a job, which is stored in the image memory 72 after the implementation of the density correction, is subjected to the gamma process and screen process corresponding to the density correction amount (latest correction amount) after the density correction. In this manner, the job which is stored in the image memory 72 after the implementation of the density correction is carried out using the latest correction amount.

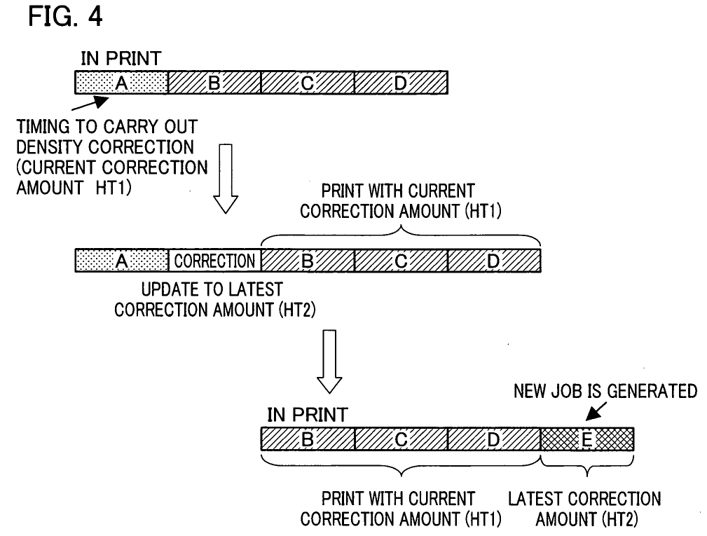

For example, as shown in FIG. 4, in a case where the image memory 72 stores jobs A-D and the density correction condition is satisfied while the job A is being executed, the density correction is carried out in the midst of the execution of the job A or after the completion of the job A. Therefore, as a matter of course, as to the job A which is executed before the implementation of the density correction, the density correction amount (current correction amount HT1) before the density correction is used as the image formation condition. After the density correction, a new image formation condition is set, i.e. a latest density correction amount (latest correction amount HT2) is worked out.

As to the jobs B-D which are on standby when the density correction condition is satisfied, the latest correction amount has been worked out before the execution of these jobs. However, since the latest correction amount HT2 had not been worked out when the jobs B-D were stored in the image memory 72, the jobs B-D have been subjected to the image processing (gamma process and screen process) corresponding to the current correction amount HT1. On this account, the image formation condition when the jobs B-D are executed is the current correction amount HT1.

If, after the density correction, a job E newly comes up, the image processing (gamma process and screen process) performed with respect to the job E corresponds to the latest correction amount HT2. On this account, the image formation condition when the job E is executed is the latest correction amount HT2.

To perform the process above, the correction amount storing section 73 of the image forming apparatus includes a current correction amount storing section 731 and a latest correction amount storing section 732, and hence the correction amount storing section 73 can store both of these correction amounts at the same time. In the example above, once the job D is completed, the current correction amount HT1 becomes unnecessary, and the latest correction amount HT2 becomes a new current correction amount.

The image forming apparatus uses these two correction amounts. On this account, even when the density correction is carried out interrupting the job on standby, the image quality is kept stable without subjecting the job on standby to the image processing such as the gamma process and the screen process again. As to the job newly inputted after the density correction, a new correction amount is used for the same. With this, the substantial retardation of the density correction is prevented, so that the long-term stability of the image quality is assured.

As described above, the image forming apparatus of the present embodiment, which includes an electrophotographic image forming section, includes: an image memory capable of storing sets of image data corresponding to a plurality of jobs; an image processing section that performs image processing with respect to the image data to be outputted; and a density correction section that changes the image formation condition of the image forming section, in order to allow the image forming section to perform the density correction in a case where the image forming section satisfies the density correction condition. The image data which is on standby and stored in the image memory has been subjected to at least a part of the image processing carried out by the image processing section. If the density correction condition of the image forming section is satisfied while a job is being executed, the density correction is performed after the job is completed or while the job is being executed. As to the job stored in the image memory when the density correction condition of the image forming section is satisfied, the job is carried out in the image formation condition before the density correction.

According to the arrangement above, in a case where the density correction condition of the image forming section is satisfied while a print job is being executed, the density correction is carried out after the job is completed or while the job is being executed. Therefore, after the timing to carry out the density correction comes, the substantial retardation of the density correction is prevented, and hence the density correction is promptly carried out.

In a case where there is a job on standby in the image memory when the density correction condition of the image forming section is satisfied, the job is executed after the completion of the density correction. Such a job on standby is executed in the image formation condition before the density correction. For this reason, the image processing (gamma process and screen process) having been performed with respect to the job agrees with the image forming condition at the time of executing the job. The printing is therefore suitably carried out.

With respect to a job which is stored in the image memory after the density correction, the above-described image forming apparatus performs image processing corresponding to the image formation condition after the density correction, and executes the job in the image formation condition after the density correction.

According to the arrangement above, the job which is stored in the image memory after the density correction is subjected to optimal image processing and optimally executed, in accordance with the latest image formation condition after the density correction.

In the image forming apparatus, the image formation condition may be a developing bias voltage or a charging bias voltage. According to this arrangement, the density correction is easily carried out.

### Embodiment 2

The following will describe another embodiment of the present invention with reference to figures. The description on an image forming apparatus of the present embodiment is omitted, because it is basically identical with the image forming apparatus of FIG. 2.

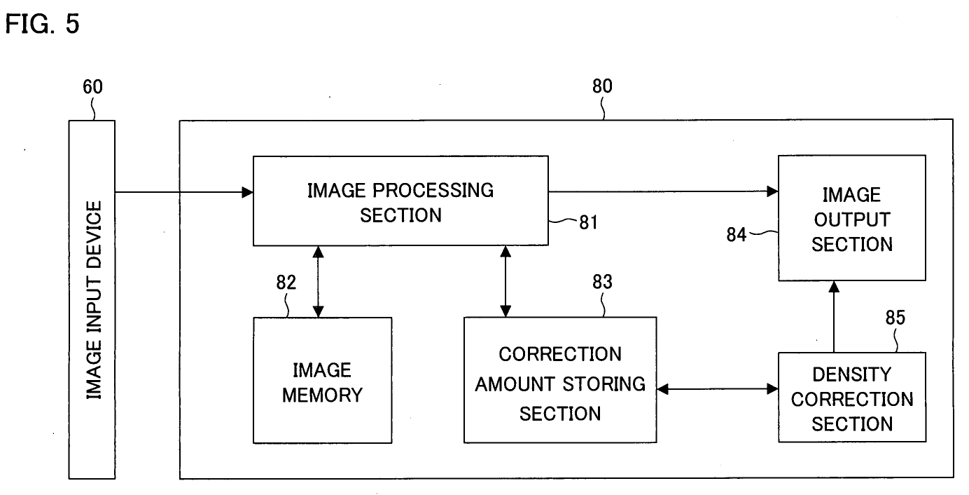

The image forming apparatus of the present embodiment forms images by electrophotography, and includes an image memory that can store a plurality of jobs. Also, the image forming apparatus of Embodiment 2 can form color images. As an embodiment of the image forming apparatus of the present invention, FIG. 5 shows a digital color multifunction device. As shown in FIG. 5, the digital color multifunction device includes an image input device 60 and an image output device 80.

The image input device 60 in this embodiment may be identical with that of Embodiment 1, and the image input device 60 supplies image data to the image output device 80. In Embodiment 2, the image input device 60 is capable of outputting color image data. The image output device 80 performs predetermined image processing with respect to the image data supplied from the image input device 60, and outputs the image data, which has been subjected to the image processing, onto a recording medium (e.g. paper). The image formation is carried out by electrophotography.

The image output device 80 includes an image processing section 81, an image memory 82, a correction amount storing section 83, an image output section 84, and a density correction section 85. These members of the image output device 80 is controlled by a control section (not illustrated).

The image processing section 81 performs the image processing such as the gamma process and screen process with respect to the image data supplied from the image input device 60, and then outputs the image data to the image output section 84. The image processing section 81 is identical with the image processing section 71 shown in FIG. 3, in terms of arrangement and function. The description of the image processing section 81 is therefore omitted.

The image memory 82 temporarily stores the image data supplied from the image input device 60, i.e. stores a print request job. Since the image forming apparatus includes the image memory 82, the image forming apparatus can store a plurality of jobs in such a manner that, when the execution of a job is requested while another job is being executed, the newly-requested job is stored in the image memory 82.

Subsequently, the density correction by the image output section 84 is performed in such a manner that the density correction section 85 changes the image formation condition of the image output section 84. The image output section 84 and the density correction section 85 are identical with the image output section 74 and the density correction section 75, respectively, in terms of arrangement and function. The description of these members is therefore omitted.

At the time of the density correction, the image formation condition figured out by the density correction section 85 is stored in the correction amount storing section 85, as a correction amount indicating to what extent the developing bias voltage, the charging potential, and the like are corrected.

Since the image forming apparatus of the present embodiment generates color images, the density correction is carried out for the image forming section of each color.

The objective of the image forming apparatus of the present embodiment is as follows: in a case where the density correction condition is satisfied while a print job is being executed, and at the same time the image memory stores image data on standby, the density correction is promptly carried out and also all print jobs stored in the image memory 82 are suitably performed.

To achieve the objective, when the density correction condition is satisfied and the density correction is performed while another job is being executed, the image forming apparatus changes the order of output of standby jobs which have been subjected to the gamma process and screen process and are stored in the image memory 82, in order to differentiate the processing to which a color job is subjected from the processing to which a monochrome job is subjected.

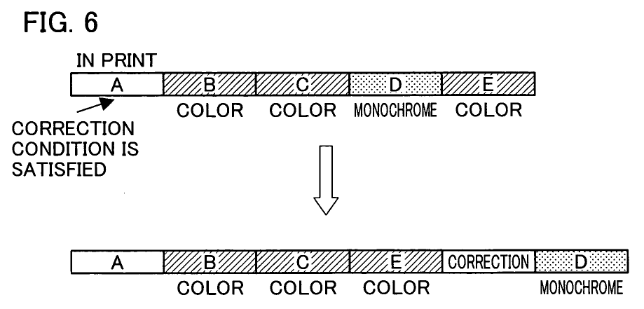

For example, assume that, as shown in FIG. 6, the image memory 82 stores jobs A-E and the density correction condition is satisfied while the job A is being executed. In such a case, the jobs B-E on standby are classified into color job and monochrome job, and the order of the jobs to be outputted is rearranged. More specifically, priority is given to the jobs B, C, and E which are color jobs over the job D which is a monochrome job.

The color jobs are executed before the density correction, and the density correction is carried out immediately after the execution of the color jobs. Then the monochrome job is executed.

In this manner, if the timing to perform the density correction comes while a job is being executed, only color jobs among the jobs which are on standby and stored in the image memory 82 are executed. With this, as to the color jobs, the image processing (gamma process and screen process), to which the jobs have been subjected at the time of being stored in the image memory 82, agree with the image formation condition at the time of executing the jobs.

That is, in a case where the image processing to which a job is subjected disagrees with the image formation condition at the time of executing the job, the density correction is not suitably carried out, and hence the density as a result of the density correction deviates from the original density of the image to some degree. In regard of color jobs, such deviation occurs in each basic color (e.g. C, M, Y). The accumulation of deviations may deteriorate the hue of the image and induce conspicuous deterioration of image quality. The method described above makes it possible to surely avoid such image quality deterioration in connection with color jobs.

In the meanwhile, as to monochrome jobs, even if the image processing to which the job is subjected disagrees with the image formation condition at the time of executing the job and hence a certain degree of deviation from the original density of the image occurs, the deviation does not deteriorate the hue of the image. Therefore, conspicuous deterioration of image quality does not occur in this case.

On this account, the monochrome job which is on standby at the timing of performing the density correction is executed after the density correction, i.e. the density correction is executed before the execution of the monochrome job. That is, the density correction is carried out before the printing of the monochrome data, so that unnecessary retardation of the implementation of the density correction is prevented, and hence the long-term stability of the image quality is assured.

As described above, the image forming apparatus of the present embodiment, which includes an electrophotographic image forming section, includes: an image memory capable of storing sets of image data corresponding to a plurality of jobs; an image processing section that performs image processing with respect to the image data to be outputted; and a density correction section that changes the image formation condition of the image forming section, in order to allow the image forming section to perform the density correction in a case where the image forming section satisfies the density correction condition. The image data which is on standby and stored in the image memory has been subjected to at least a part of image processing carried out by the image processing section. In a case where the density correction condition of the image forming section is satisfied while a job is being executed, the jobs stored in the image memory are classified into color job and monochrome job, and the density correction is performed after the color jobs are preferentially executed. Then, after the density correction, the monochrome jobs are executed.

According to the arrangement above, since the density correction is carried out after the color jobs are executed, the image processing to which the color jobs are subjected agrees with the image formation condition at the time of executing the color jobs. Therefore, as to the color jobs, it is possible to surely prevent the occurrence of the image quality deterioration which occurs when the image processing performed with respect to the jobs disagrees with the image formation condition at the time of executing the jobs.

As to the monochrome jobs, even if the image processing to which the jobs have been subjected disagrees with the image formation condition at the time of executing the jobs, conspicuous deterioration of image quality does not occur. On this account, the execution of the monochrome jobs is carried out after the density correction. With this, unnecessary retardation of the density correction is prevented and hence the long-term stability of the image quality is assured.

In the above-described image forming apparatus, the image formation condition may be a developing bias voltage or a charging bias voltage. This makes it easy to perform the density correction.

### Embodiment 3

The following will describe a further embodiment of the present invention in reference to figures. An image forming apparatus of the present embodiment is basically identical with the image forming apparatus of FIG. 2. Detailed description of the image forming apparatus of the present embodiment is therefore omitted.

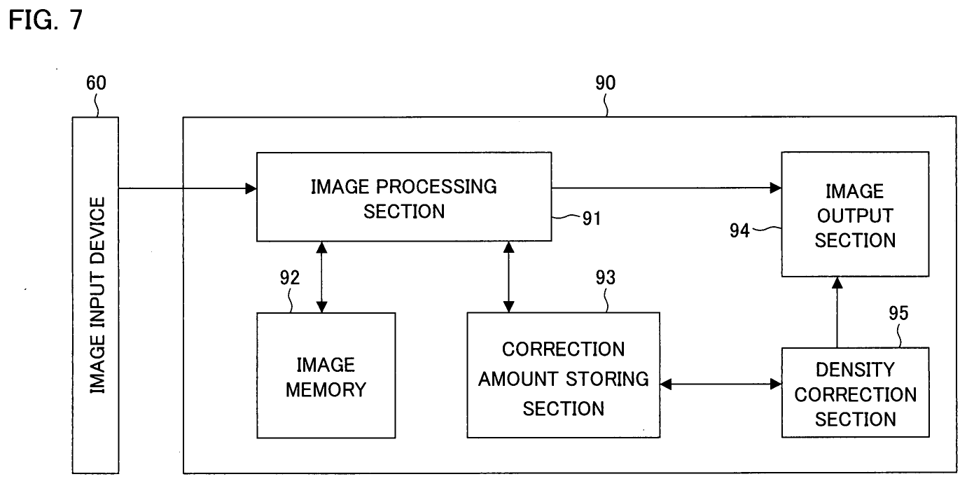

The image forming apparatus of the present invention forms images by electrophotography, and includes an image memory that can store a plurality of jobs. As an embodiment of the image forming apparatus of the present invention, FIG. 7 shows a digital color photocopier. As shown in FIG. 7, the digital color photocopier includes an image input device 60 and an image output device 90.

The image input device 60 may be identical with that of Embodiment 1, and the image input device 60 supplies image data to the image output device 90. The image output device 90 performs predetermined image processing with respect to image data supplied from the image input device 60, and outputs the image data, which has been subjected to the image processing, onto a recording medium (e.g. paper). The image formation is performed by electrophotography.

The image output device 90 includes an image processing section 91, an image memory 92, a correction amount storing section 93, an image output section 94, and a density correction section 95. These members of the image output device 90 is controlled by a control section (not illustrated).

The image processing section 91 subjects the image data, which is supplied from the image input device 60, to the image processing including the gamma process and screen process, and outputs the processed image data to the image output section 94. The image processing section 91 is identical with the image processing section 71 shown in FIG. 3, in terms of arrangement and function. Detailed description of the image processing section 91 is therefore omitted.

The image memory 22 temporarily stores image data supplied from the image input device 60, i.e. stores a print request job. Since the image forming apparatus includes the image memory 92, the image forming apparatus can store a plurality of jobs in such a manner that, when the execution of a job is requested while another job is being executed, the newly-requested job is stored in the image memory 92.

Subsequently, the density correction by the image output section 94 is carried out in such a manner that the density correction section 95 changes the image formation condition of the image output section 94. The image output section 94 and the density correction section 95 are identical with the image output section 74 and the density correction section 75 shown in FIG. 3, respectively, in terms of the arrangements and functions. Detailed description of these members are therefore omitted.

In a case where the image forming apparatus of the present embodiment generates a color image, the density correction is carried out for the image forming section of each color.

The objective of the image forming apparatus of the present embodiment is as follows: in a case where the density correction condition is satisfied while a print job is being executed, the density correction is promptly carried out and also all print jobs stored in the image memory 82 are suitably executed, irrespective of whether or not the image memory 92 stores image data on standby when the density correction condition is satisfied.

Therefore, the above-described image forming apparatus determines whether or not the image memory 92 stores image data on standby, when the density correction condition is satisfied while a job is being executed. Then the image forming apparatus differentiates the density correction in a case where there is a job on standby from the density correction in a case where there is no job on standby.

More specifically, if image data on standby is stored in the image memory 92 when the density correction condition is satisfied while a job is being executed, the density correction is carried out in a simple mode, and hence the time required for the density correction is short. Meanwhile, if there is no image data on standby in the image memory 92, the density correction is performed in a high-definition mode which is normally used.

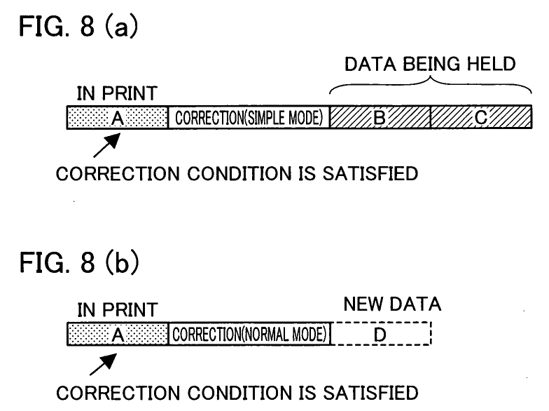

For example, assume that, as shown in FIG. 8(a), the image memory stores jobs A-C and the density correction condition is satisfied while the job A is being executed. In this case, the density correction is carried out in the simple mode, after the completion of the job A. Therefore, the jobs B and C which have been on standby are executed after the density correction above is implemented. Since this density correction is performed in the simple mode, the time required for this correction is shorter than the time required for the normal density correction. On this account, the waiting time of the jobs B and C is minimized so that the printing performance does not deteriorate.

In the meanwhile, as shown in FIG. 8(b), the deterioration of the printing performance does not occur even if the normal density correction is carried out, in a case where there are no jobs other than the job A being executed (i.e. there are no jobs on standby in the image memory 92), at the time that the density correction condition is satisfied. On this account, if there is no image data on standby in the image memory 92 at the time that the density correction condition is satisfied, the density correction is carried out in the normal high-definition mode. In this case, the image formation condition is optimal as compared to the case where the density correction is performed in the simple mode. With this, the image quality of a new job D generated after the completion of the density correction is assured.

Alternatively, the image forming apparatus may be arranged as follows: after the density correction is performed in the simple mode, the density correction is performed in the normal high-definition mode, when the image memory 92 no longer stores jobs on standby.

In the aforesaid simple mode, the density correction is performed in a short period of time, as compared to the density correction in the normal mode. A specific example of the density correction in the normal mode is such that the number of patterns of patch images formed at the time of the density correction is reduced as compared to the number in the normal mode. That is, when the density correction is carried out, a plurality of toner images (patch images) are formed on the photoconductor, transfer material transport belt, or the like, and the image formation condition for obtaining a desired density is figured out by, for example, detecting the optical characteristics such as amounts of reflected light beams from the toner images. In the density correction in the simple mode, the number of the pattern of the patch images is reduced as compared to the number in the normal mode. On this account, the time required for figuring out the image formation condition is shortened, and hence the density correction is performed in a short period of time as compared to the normal mode.

As described above, according to the above-described image forming apparatus, in a case where the density correction condition is satisfied while the density correction is carried out interrupting the job on standby, the density correction is carried out in the simple mode. With this, the job on standby is executed with a stable image quality, and the substantial retardation of the implementation of the density correction is prevented. Therefore long-term stability of the image quality is assured.

As described above, the forming apparatus of the present invention, which includes an electrophotographic image forming section, is provided with: an image memory capable of storing sets of image data corresponding to a plurality of jobs: an image processing section that performs image processing with respect to a set of image data to be outputted: and a density correction section that changes an image formation condition of the image forming section, for causing the image forming section to perform the density correction in a case where the image forming section satisfies a density correction condition, a set of image data which is on standby for printing being stored in the image memory, in a state of having been subjected to at least a part of the image processing performed by the image processing section, and when the density correction condition of the image forming section is satisfied while a job is being executed, the density correction being performed in a normal mode if there is no job in the image memory, meanwhile, when the density correction condition of the image forming section is satisfied while a job is being executed, the density correction being performed in a simple mode in which a time required for the density correction is short as compared to the normal mode, if there is a job in the image memory.

According to the arrangement above, in a case where the density correction condition is satisfied while a job is being executed, the density correction is carried out after the execution of the job. On this account, after the timing to carry out the density correction comes, the substantial retardation of the density correction of prevented, and the density correction is promptly carried out.

In a case where a job on standby for printing is stored in the image memory when the density correction condition of the image forming section is satisfied, the density correction is performed in the simple mode with which a time required for the density correction is short as compared to the normal mode. The job on standby is therefore executed after the density correction. A time required for this density correction is shorter than that for the normal density correction. On this account, a time for standby is minimized and the deterioration of the printing performance is restrained.

Furthermore, in the aforesaid image forming apparatus, after the density correction is performed in the simple mode, the density correction is performed again in the normal mode, once there is no longer a job on standby in the image memory.

According to the arrangement above, after the density correction is performed in the simple mode, the density correction is performed again in the normal mode. On this account, as to a job newly generated thereafter, stably image quality is assured.

The aforesaid image forming apparatus is characterized in that, in a case where the density correction is performed in the simple mode, the number of patterns of image patches is reduced as compared to the density correction in the normal mode. According to this arrangement, the density correction in the simple mode is easily carried out.

Furthermore, in the image forming apparatus, the image formation condition is either a developing bias voltage or a charging bias voltage. According to this arrangement, the density correction is easily carried out.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An image forming apparatus including an electrophotographic image forming section,
the image forming apparatus comprising:
an image memory capable of storing sets of image data corresponding to a plurality of jobs:
an image processing section that performs image processing with respect to a set of image data to be outputted: and
a density correction section that changes an image formation condition of the image forming section, for causing the image forming section to perform the density correction in a case where the image forming section satisfies a density correction condition,
a set of image data which is on standby for printing being stored in the image memory, in a state of having been subjected to at least a part of the image processing performed by the image processing section,
in a case where the density correction condition of the image forming section is satisfied while a job is being executed, the density correction being performed either while the job is being executed or after the job is executed, and
a job, which has been stored in the image memory when the image forming section satisfies the density correction condition, being executed in an image formation condition determined before the density correction is performed.

2. The image forming apparatus as defined in claim 1, wherein, a job, which is stored in the image memory after the density correction is performed, is subjected to image processing corresponding to an image formation condition determined after the density correction is performed, and the job is executed in the image formation condition determined after the density correction is performed.

3. An image forming apparatus including an electrophotographic image forming section,
the image forming apparatus comprising:
an image memory capable of storing sets of image data corresponding to a plurality of jobs:
an image processing section that performs image processing with respect to a set of image data to be outputted: and
a density correction section that changes an image formation condition of the image forming section, for causing the image forming section to perform the density correction in a case where the image forming section satisfies a density correction condition,
a set of image data which is on standby for printing being stored in the image memory, in a state of having been subjected to at least a part of the image processing performed by the image processing section, and
in a case where the density correction condition of the image forming section is satisfied while a job is being executed, jobs stored in the image memory being classified into color jobs and monochrome jobs, the density correction being performed after the color jobs are preferentially executed, and the monochrome jobs being executed after the density correction is performed.

4. An image forming apparatus including an electrophotographic image forming section,
the image forming apparatus comprising:
an image memory capable of storing sets of image data corresponding to a plurality of jobs:
an image processing section that performs image processing with respect to a set of image data to be outputted: and
a density correction section that changes an image formation condition of the image forming section, for causing the image forming section to perform the density correction in a case where the image forming section satisfies a density correction condition,
a set of image data which is on standby for printing being stored in the image memory, in a state of having been subjected to at least a part of the image processing performed by the image processing section, and
when the density correction condition of the image forming section is satisfied while a job is being executed, the density correction being performed in a normal mode if there is no job in the image memory, meanwhile, when the density correction condition of the image forming section is satisfied while a job is being executed, the density correction being performed in a simple mode in which a time required for the density correction is short as compared to the normal mode, if there is a job in the image memory.

5. The image forming apparatus as defined in claim 4, wherein, after the density correction is performed in the simple mode, the density correction is performed again in the normal mode, once there is no longer a job on standby in the image memory.

6. The image forming apparatus as defined in claim 4, wherein, in a case where the density correction is performed in the simple mode, the number of patterns of image patches is reduced as compared to the density correction in the normal mode.

7. The image forming apparatus as defined in claim 1, wherein, the image formation condition is a developing bias voltage.

8. The image forming apparatus as defined in claim 3, wherein, the image formation condition is a developing bias voltage.

9. The image forming apparatus as defined in claim 4, wherein, the image formation condition is a developing bias voltage.

10. The image forming apparatus as defined in claim 1, wherein, the image formation condition is a charging bias voltage.

11. The image forming apparatus as defined in claim 3, wherein, the image formation condition is a charging bias voltage.

12. The image forming apparatus as defined in claim 3, wherein, the image formation condition is a charging bias voltage.
